(19) United States
(12) Patent Application Publication
(10) Pub. No.: US 2013/0126872 A1
(43) Pub. Date: May 23, 2013

(54) ORGANIC LIGHT-EMITTING DISPLAY APPARATUS

(71) Applicant: Kyu-Sik Cho, Yongin-city (KR)

(72) Inventor: Kyu-Sik Cho, Yongin-city (KR)

(21) Appl. No.: 13/528,959

(22) Filed: Jun. 21, 2012

(30) Foreign Application Priority Data
Nov. 21, 2011 (KR) 10-2011-0121735

(51) Int. Cl. H01L 27/32

(52) U.S. Cl. 257/59; 257/72; 257/E27.119; 257/40

(57) ABSTRACT

An organic light-emitting display includes a substrate, a first electrode on the substrate, an intermediate layer on the first electrode, and including an organic light-emitting layer, a second electrode on the intermediate layer, and a reflective member on sides of the intermediate layer to reflect visible light generated by the intermediate layer, the reflective member contacting the second electrode.

### CROSS-REFERENCE TO RELATED PATENT APPLICATION

This application claims priority to and the benefit of Korean Patent Application No. 10-2011-0121735, filed on Nov. 21, 2011, in the Korean Intellectual Property Office, the disclosure of which is incorporated herein in its entirety by reference.

### BACKGROUND

1. Field

The present invention relates to an organic light-emitting display apparatus.

2. Description of Related Art

Portable flat panel display devices have recently become popular. Organic light-emitting display apparatuses, which are self-emissive display devices from among flat panel display devices, are given attention as next-generation display devices because the organic light-emitting display apparatuses have a wide viewing angle, high contrast, and fast response time.

An organic light-emitting display apparatus includes an intermediate layer, a first electrode, and a second electrode. The intermediate layer includes an organic light-emitting layer that generates visible light when a voltage is applied across the first electrode and the second electrode.

The visible light generated by the organic light-emitting layer travels toward a user/viewer of the organic light-emitting display apparatus, and the user recognizes an image. However, part of the visible light generated by the organic light-emitting layer does not travel toward the user.

Accordingly, the light efficiency of the organic light-emitting display apparatus is reduced and there is a limitation in improving image quality.

### SUMMARY

Embodiments of the present invention provide an organic light-emitting display apparatus that improves image quality.

According to an embodiment of the present invention, there is provided an organic light-emitting display apparatus including a substrate, a first electrode on the substrate, an intermediate layer on the first electrode, and including an organic light-emitting layer, a second electrode on the intermediate layer, and a reflective member on sides of the intermediate layer to reflect visible light generated by the intermediate layer, the reflective member contacting the second electrode.

The organic light-emitting display apparatus may further include a pixel defining layer between the reflective member and the second electrode, wherein the pixel defining layer includes a first opening corresponding to the intermediate layer, and a second opening corresponding to the reflective member, and wherein the reflective member and the second electrode contact each other in the second opening.

The second opening may extend corresponding to at least one side surface of the intermediate layer.

A width of the second opening may increase away from the substrate.

The second electrode may include a contact portion contacting a top surface of the reflective member in the second opening, and a side portion at a side of the second opening.

A surface of the side portion of the second electrode adjacent to the intermediate layer may be at an angle with the substrate.

The reflective member may extend corresponding to at least one side surface of the intermediate layer.

The reflective member may be spaced from the first electrode.

The organic light-emitting display apparatus may further include a thin film transistor (TFT) on the substrate, the TFT being electrically connected to the first electrode, and including an active layer, a gate electrode, a source electrode, and a drain electrode.

The reflective member may be spaced from the source electrode and the drain electrode.

The reflective member may include a same material as the gate electrode, the source electrode, or the drain electrode.

The reflective member may include a first member including a same material as the gate electrode, and a second member on the first member and including a same material as the source electrode and/or the drain electrode.

The organic light-emitting display apparatus may further include a conductive member on the first electrode and electrically connected to the source electrode or the drain electrode.

The organic light-emitting display apparatus may further include a reflective layer on the conductive member.

The reflective layer may extend corresponding to a side surface of the intermediate layer.

The reflective layer may be spaced from the reflective member.

The reflective layer may be spaced from the source electrode and the drain electrode.

The reflective layer may be electrically connected to any one of the source electrode and the drain electrode, and the source electrode or the drain electrode electrically connected to the reflective layer may be electrically connected to the first electrode.

The gate electrode and the first electrode may be at a same layer.

The gate electrode may include a first conductive layer, and a second conductive layer on the first conductive layer, wherein the first electrode includes a same material as the first conductive layer, and the reflective member may include a first member including a lower layer including a same material as the first conductive layer of the gate electrode, and an upper layer on the lower layer and including a same material as the second conductive layer of the gate electrode, and a second member on the first member and including a same material as the source electrode and/or the drain electrode.

### BRIEF DESCRIPTION OF THE DRAWINGS

The above and other features and aspects of embodiments of the present invention will become more apparent by describing in detail exemplary embodiments thereof with reference to the attached drawings in which:

FIG. 1 is a cross-sectional view illustrating an organic light-emitting display apparatus according to an embodiment of the present invention;

FIG. 2 is a partial plan view illustrating a portion P of the organic light-emitting display apparatus of the embodiment shown in FIG. 1, the portion P being seen in an A direction, as indicated in FIG. 1;

FIG. 3 is a cross-sectional view illustrating an organic light-emitting display apparatus according to another embodiment of the present invention;

FIG. 4 is a partial plan view illustrating a portion P of the organic light-emitting display apparatus of the embodiment shown in FIG. 3, the portion P being seen in an A direction, as indicated in FIG. 3;

FIG. 5 is a cross-sectional view illustrating an organic light-emitting display apparatus according to another embodiment of the present invention; and

FIG. 6 is a partial plan view illustrating a portion P of the organic light-emitting display apparatus of the embodiment shown in FIG. 5, the portion P being seen in an A direction.

### DETAILED DESCRIPTION

Embodiments of the present invention will now be described more fully with reference to the accompanying drawings, in which exemplary embodiments of the invention are shown.

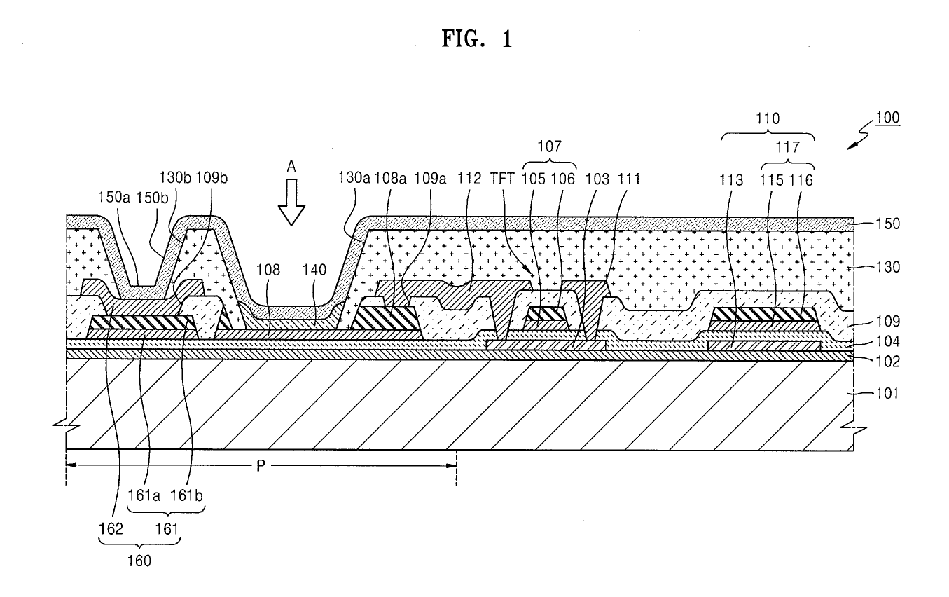

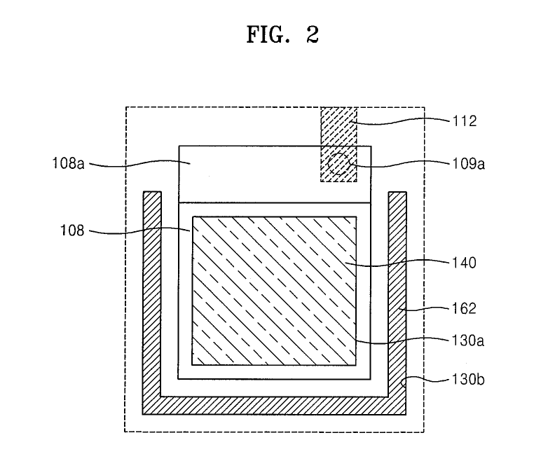

FIG. 1 is a cross-sectional view illustrating an organic light-emitting display apparatus 100 according to an embodiment of the present invention. FIG. 2 is a partial plan view illustrating a portion P of the organic light-emitting display apparatus 100 shown in FIG. 1 and seen in an A direction. For convenience of explanation, only an intermediate layer 140, a first electrode 108, a conductive portion 108a, a second member 162 of a reflective member 160, a drain electrode 112, a contact hole 109a, a first opening 130a, and a second opening 130b are illustrated in FIG. 2.

In order to be easily distinguished from the second member 162 of the reflective member 160 in FIG. 2, the drain electrode 112 and the contact hole 109a are indicated by dashed lines. Also, only a top surface of the second member 162 exposed through the second opening 130b from among surfaces of the second member 162 is illustrated in FIG. 2.

Referring to FIGS. 1 and 2, the organic light-emitting display apparatus 100 includes a substrate 101, a thin film transistor (TFT), the first electrode 108, the intermediate layer 140, a second electrode 150, the reflective member 160, and a capacitor 110.

The TFT includes an active layer 103, a gate electrode 107, a source electrode 111, and a drain electrode 112. The capacitor 110 includes a first capacitor electrode 113 and a second capacitor electrode 117. The reflective member 160 includes a first member 161 and the second member 162.

Each element will be explained in detail below.

The substrate 101 may be formed of, for example, a transparent glass material having SiO₂ as a main component, although the substrate 101 is not limited thereto, and may also be formed of a transparent plastic material. In the latter scenario, the plastic material for forming the substrate 101 may be at least one selected from various organic materials.

A buffer layer 102 is formed on the substrate 101. The buffer layer 102 may include SiO₂ or SiNₓ. The buffer layer 102 planarizes a top surface of the substrate 101 and reduces or prevents moisture and impurities from penetrating into the substrate 101.

The active layer 103 and the first capacitor electrode 113 are formed on the buffer layer 102. The active layer 103 and the first capacitor electrode 113 may be formed of the same material. Each of the active layer 103 and the first capacitor electrode 113 includes a semiconductor material. For example, the active layer 103 and the first capacitor electrode 113 include amorphous silicon or polycrystalline silicon.

A gate insulating film 104 is formed on the buffer layer 102 to cover the active layer 103 and the first capacitor electrode 113.

The gate electrode 107, the first electrode 108, the first member 161 of the reflective member 160, and the second capacitor electrode 117 are formed on the gate insulating film 104.

The gate electrode 107 includes a first conductive layer 105 and a second conductive layer 106. The first conductive layer 105 may include a transparent conductive material, for example, indium tin oxide (ITO).

The second conductive layer 106 may be formed on the first conductive layer 105 to include, for example, a metal or a metal alloy such as molybdenum (Mo), molybdenum-tungsten (MoW), or an aluminum (Al)-based alloy, but the present embodiment is not limited thereto.

The first electrode 108 may include a transparent conductive material and may be formed of the same material as that of the first conductive layer 105.

The conductive portion 108a is located on a portion of a top surface of the first electrode 108, and is formed of the same material as that of the second conductive layer 106.

The first member 161 of the reflective member 160 is formed to be spaced apart from the first electrode 108. The first member 161 includes a lower layer 161a and an upper layer 161b. The lower layer 161a is formed of the same material as that of the first conductive layer 105, and the upper layer 161b is formed of the same material as that of the second conductive layer 106.

The second capacitor electrode 117 includes a first layer 115 and a second layer 116. The first layer 115 is formed of the same material as that of the first conductive layer 105, and the second layer 116 is formed of the same material as that of the second conductive layer 106.

An interlayer insulating film 109 is formed on the first electrode 108, the gate electrode 107, the first member 161, and the second capacitor electrode 117. The interlayer insulating film 109 may include any of various insulating materials such as an organic material or an inorganic material.

The source electrode 111, the drain electrode 112, and the second member 162 of the second reflective member 160 are formed on the interlayer insulating film 109. The source electrode 111 and the drain electrode 112 are formed to be electrically connected to the active layer 103. Each of the source electrode 111 and the drain electrode 112 may be formed of any of various materials, for example, a metal such as gold (Au), palladium (Pd), platinum (Pt), nickel (Ni), rhodium (Rh), ruthenium (Ru), iridium (Ir), osmium (Os), aluminum (Al), molybdenum (Mo), neodymium (Nd), tungsten (W), or an alloy of at least two of the metals, although the present embodiment is not limited thereto.

Any one of the source electrode 111 and the drain electrode 112 is electrically connected to the first electrode 108. In the present embodiment, the drain electrode 112 is electrically connected to the first electrode 108 in FIGS. 1 and 2. In detail, the interlayer insulating film 109 includes the contact hole 109a, and a first end of the drain electrode 112 longitudinally extends (see FIG. 2) to contact the conductive portion 108a via the contact hole 109a.

The second member 162 is formed on the first member 161. In detail, the interlayer insulating film 109 includes a first via hole 109b, and the second member 162 is formed to correspond to the first via hole 109b. The second member 162 may be formed of the same material as that of the source electrode 111 or the drain electrode 112.

A pixel defining layer 130 is formed on the TFT and the reflective member 160. The pixel defining layer 130 is formed to expose a portion of the top surface of the first electrode 108 (e.g., through the first opening 130a), and the intermediate layer 140 is formed to contact the first electrode 108. The intermediate layer 140 includes an organic light-emitting layer (not shown).

In detail, the pixel defining layer 130 includes the first opening 130a and the second opening 130b. The first opening 130a is formed to correspond to the portion of the top surface of the first electrode 108, and the intermediate layer 140 is formed in the first opening 130a and is electrically connected to the first electrode 108.

The second opening 130b of the pixel defining layer 130 is formed to correspond to a portion of a top surface of the second member 162 of the reflective member 160. In the present embodiment, at least a surface of the second opening 130b (e.g., a surface of the pixel defining layer 130 in the second opening 130b) adjacent to the intermediate layer 140 may be inclined at an angle (e.g., an acute angle) with respect to the substrate 101. For example, a width of the second opening 130b may increase upward from the substrate 101, that is, farther away from the substrate 101.

The second electrode 150 is formed on the intermediate layer 140, and corresponds to the second opening 130b, and is electrically connected to the reflective member 160. In detail, the second electrode 150 includes a contact portion 150a contacting the second member 162 in the second opening 130b, and a side portion 150b located at a side of the second opening 130b (e.g., a side of the pixel defining layer 130 in the second opening 130b).

When a voltage is applied through the first electrode 108 and the second electrode 150 (e.g., across the first electrode 108 and the second electrode 150), the organic light-emitting layer of the intermediate layer 140 generates visible light.

The reflective member 160 is formed around the intermediate layer 140 (e.g., on three sides of the intermediate layer 140, see FIG. 2). In detail, the reflective member 160 may be formed to correspond to a side surface other than a side surface of the intermediate layer 140 adjacent to the conductive portion 108a from among side surfaces of the intermediate layer 140.

The second opening 130b is formed around the intermediate layer 140 to correspond to the reflective member 160, and the second electrode 150 is formed in the second opening 130b. Accordingly, the contact portion 150a and the side portion 150b of the second electrode 150 may be formed to correspond to the side surface of the intermediate layer 140. In detail, the contact portion 150a and the side portion 150b of the second electrode 150 may be formed to correspond to a side surface other than a side surface of the intermediate layer 140 adjacent to the conductive portion 108a from among side surfaces of the intermediate layer 140.

Accordingly, light traveling from the side surface of the intermediate layer 140 from among the visible light generated by the intermediate layer 140 is reflected by the reflective member 160 toward a user.

Also, due to the side portion 150b and the contact portion 150a of the second electrode 150 formed on the reflective member 160, the light traveling toward the user is efficiently condensed. In particular, the side portion 150b of the second electrode 150 effectively reduces or prevents the light traveling from the side surface of the intermediate layer 140 from among the visible light generated by the intermediate layer 140 from being outwardly discharged away from the user, and effectively leads to light reflection in the organic light-emitting display apparatus 100, thereby improving light efficiency through optical resonance.

In particular, since the second opening 130b is inclined at the acute angle with respect to the substrate 101, most of the visible light generated by the intermediate layer 140 travels downward to the substrate 101.

The reflective member 160 includes the first member 161 and the second member 162 in FIGS. 1 and 2. However, the first member 161 and the second member 162 need not be separately formed, but may also be integrally formed with each other. That is, the reflective member 160 may be formed of the same material as that of the gate electrode 107, and the reflective member 160 may also be formed of the same material as that of the source electrode 111 and/or the drain electrode 112.

A sealing member (not shown) may be formed on the second electrode 150 to protect the intermediate layer 140 and other layers from external moisture or oxygen. To this end, the sealing member may be formed of any of various materials such as glass, plastic, an organic material, an inorganic material, or a combination of an organic material and an inorganic material.

In the organic light-emitting display apparatus 100 of the present embodiment, the reflective member 160 is formed to correspond to a side surface of the intermediate layer 140. Light traveling from the side surface of the intermediate layer 140 from among visible light generated by the intermediate layer 140 is reflected by the reflective member 160 toward a user, thereby improving the light efficiency of the organic light-emitting display apparatus 100 and also improving image quality.

The side portion 150b and the contact portion 150a of the second electrode 150 formed on the reflective member 160 effectively reduce or prevent the light traveling from the side surface of the intermediate layer 140 from among the visible light generated by the intermediate layer 140 from being outwardly discharged away from the user, and effectively leads to light reflection in the organic light-emitting display apparatus 100, thereby improving light efficiency through optical resonance.

The reflective member 160 may be formed of the same material as that of at least one of the gate electrode 107, the source electrode 111, or the drain electrode 112 to improve process convenience. The reflective member 160 may be formed at the same layer as that of the gate electrode 107, the source electrode 111, and/or the drain electrode 112 to improve image quality without increasing a thickness of the organic light-emitting display apparatus 100.

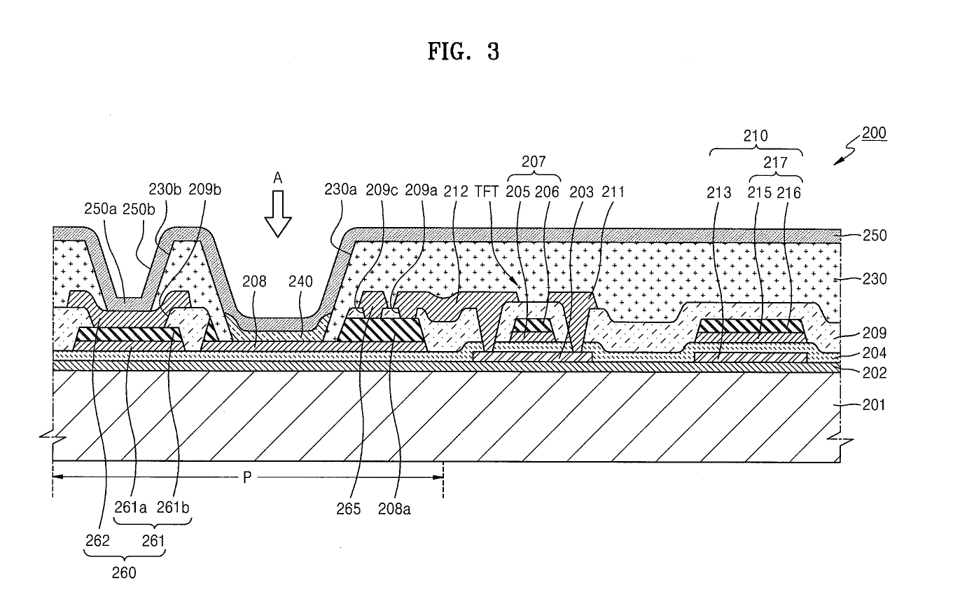

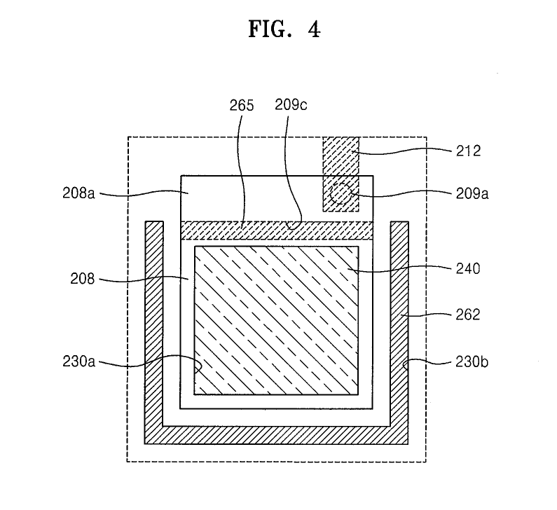

FIG. 3 is a cross-sectional view illustrating an organic light-emitting display apparatus 200 according to another embodiment of the present invention. FIG. 4 is a partial plan view illustrating a portion P of the organic light-emitting display apparatus 200 shown in FIG. 3 and seen in an A direction. For convenience of explanation, only an intermediate layer 240, a first electrode 208, a conductive portion 208a, a second member 262 of a reflective member 260, a drain electrode 212, a reflective layer 265, a contact hole 209a, a second via hole 209c, a first opening 230a, and a second opening 230b are illustrated in FIG. 4.

In order to be easily distinguished from the second member 262 of the reflective member 260 in FIG. 4, the drain electrode 212, the reflective layer 265, and the contact hole 209a are indicated by dashed lines. Also, only a top surface of the second member 262 exposed through the second opening 230b from among surfaces of the second member 262 is illustrated in FIG. 4.

Referring to FIGS. 3 and 4, the organic light-emitting display apparatus 200 includes a substrate 201, a TFT, the first electrode 208, the intermediate layer 240, a second electrode 250, the reflective member 260, the reflective layer 265, and a capacitor 210.

The TFT includes an active layer 203, a gate electrode 207, a source electrode 211, and the drain electrode 212. The capacitor 210 includes a first capacitor electrode 213 and a second capacitor electrode 217. The reflective member 260 includes a first member 261 and the second member 262.

Each element will be explained in detail below.

A buffer layer 202 is formed on the substrate 201, and the active layer 203 and the first capacitor electrode 213 are formed on the buffer layer 202. A gate insulating film 204 is formed on the buffer layer 202 to cover the active layer 203 and the first capacitor electrode 213.

The gate electrode 207, the first electrode 208, the first member 261 of the reflective member 260, and the second capacitor electrode 217 are formed on the gate insulating film 204.

The gate electrode 207 includes a first conductive layer 205 and a second conductive layer 206. The first electrode 208 may include a transparent conductive material and may be formed of the same material as that of the first conductive layer 205.

The conductive portion 208a is formed on a portion of a top surface of the first electrode 208 of the same material as that of the second conductive layer 206.

The first member 261 of the reflective member 260 is formed to be spaced apart from the first electrode 208. The first member 261 includes a lower layer 261a and an upper layer 261b. The lower layer 261a is formed of the same material as that of the first conductive layer 205 and the upper layer 261b is formed of the same material as that of the second conductive layer 206.

The second capacitor electrode 217 includes a first layer 215 and a second layer 216. The first layer 215 is formed of the same material as that of the first conductive layer 205 and the second layer 216 is formed of the same material as that of the second conductive layer 206.

An interlayer insulating film 209 is formed on the first electrode 208, the gate electrode 207, the first member 261, and the second capacitor electrode 217. The source electrode 211, the drain electrode 212, and the second member 262 of the reflective member 260 are formed on the interlayer insulating film 209. The source electrode 211 and the drain electrode 212 are formed to be electrically connected to the active layer 203.

The source electrode 211 or the drain electrode 212 is electrically connected to the first electrode 208. In the present embodiment, the drain electrode 212 is electrically connected to the first electrode 208, as shown in FIGS. 3 and 4. In detail, the interlayer insulating film 209 includes the contact hole 209a, and a first end of the drain electrode 212 longitudinally extends to contact the conductive portion 208a via the contact hole 209a.

The second member 262 is formed on the first member 261. In detail, the interlayer insulating film 209 includes a first via hole 209b, and the second member 262 is formed to correspond to the first via hole 209b.

The reflective layer 265 is formed on the conductive portion 208a. In detail, the interlayer insulating film 209 includes the second via hole 209c, and the reflective layer 265 is formed to correspond to the second via hole 209c. The reflective layer 265 longitudinally extends to correspond to a side surface of the intermediate layer 240 and is spaced apart from the reflective member 260. Also, the reflective layer 265 is formed to be spaced apart from the source electrode 211 and the drain electrode 212.

A pixel defining layer 230 is formed on the TFT and the reflective member 260. The pixel defining layer 230 is formed to expose a portion of the top surface of the first electrode 208, and the intermediate layer 240 is formed to contact the first electrode 208. The intermediate layer 240 includes an organic light-emitting layer (not shown).

In detail, the pixel defining layer 230 includes the first opening 230a and the second opening 230b. The first opening 230a is formed to correspond to the portion of the top surface of the first electrode 208, and the intermediate layer 240 is formed in the first opening 230a and is electrically connected to the first electrode 208.

The second opening 230b of the pixel defining layer 230 is formed to correspond to a portion of a top surface of the second member 262 of the reflective member 260. In this case, at least a surface of the second opening 230b (e.g., a surface of the pixel defining layer 230 in the second opening 230b) adjacent to the intermediate layer 240 from among surfaces of the second opening 230b may be inclined at an angle (e.g., an acute angle) with respect to the substrate 201. For example, a width of the second opening 230b may increase upward from the substrate 201, that is, away from the substrate 201.

The second electrode 250 is formed on the intermediate layer 240. The second electrode 250 is located in the second opening 230b to be electrically connected to the reflective member 260. In detail, the second electrode 250 includes a contact portion 250a contacting the second member 262 in the second opening 230b, and also includes a side portion 250b at a side of the second opening 230b.

The reflective member 260 is formed around the intermediate layer 240 (e.g., on three sides of the intermediate layer 240, see FIG. 4). In detail, the reflective member 260 may be formed to correspond to a side surface other than a side surface of the intermediate layer 240 adjacent to the conductive portion 208a from among side surfaces of the intermediate layer 240.

The second opening 230b is formed around the intermediate layer 240 to correspond to the reflective member 260, and the second electrode 250 is formed in the second opening 230b. Accordingly, the contact portion 250a and the side portion 250b of the second electrode 250 may be formed to correspond to the side surface of the intermediate layer 240. In detail, the contact portion 250a and the side portion 250b of the second electrode 250 may be formed to correspond to a side surface other than a side surface of the intermediate layer 240 adjacent to the conductive portion 208a from among side surfaces of the intermediate layer 240.

Accordingly, light traveling from the side portion of the intermediate layer 240 from among visible light generated by the intermediate layer is reflected by the reflective member 260 toward a user.

Also, due to the side portion 250b and the contact portion 250a of the second electrode 250 formed on the reflective member 260, the light traveling toward the user is effectively condensed. In particular, the side portion 250b of the second electrode 250 effectively reduces or prevents the light traveling from the side surface of the intermediate layer 240 from among the visible light generated by the intermediate layer 240 from being outwardly discharged away from the user, and effectively leads to light reflection in the organic light-emitting display apparatus 200, thereby improving light efficiency through optical resonance.

In particular, since the second opening 230b is inclined at the acute angle with respect to the substrate 201, most of the visible light generated by the intermediate layer 240 travels downward to the substrate 201 without being lost.

The reflective member 260 of the organic light-emitting display apparatus 200 of the present embodiment includes the first member 261 and the second member 262, as shown in FIGS. 3 and 4. However, the first member 261 and the second member 262 need not be separately formed, but may be integrally formed with each other. That is, the reflective member 260 may be formed of the same material as that of the gate electrode 207, and the reflective member 260 may be formed of the same material as that of the source electrode 211 and/or the drain electrode 212.

A sealing member (not shown) may be formed on the second electrode 250 to protect the intermediate layer 240 and other layers from external moisture or oxygen. To this end, the sealing member may be formed of any of various materials such as glass, plastic, an organic material, an inorganic material, or a combination of an organic material and an inorganic material.

In the organic light-emitting display apparatus 200, the reflective member 260 is formed to correspond to the side surface of the intermediate layer 240. Accordingly, the light efficiency of the organic light-emitting display apparatus 200 is improved, thereby improving image quality.

The side portion 250b and the contact portion 250a of the second electrode 250 formed on the reflective member 260 effectively reduce or prevent light traveling from the side surface of the intermediate layer 240 from among visible light generated by the intermediate layer 240 from being outwardly discharged away from the user, and effectively leads to light reflection in the organic light-emitting display apparatus 200, thereby improving light efficiency through optical resonance.

Also, since the conductive portion 208a and the reflective layer 265 electrically connected to the conductive portion 208a reflect light traveling from the side surface of the intermediate layer 240 to the user (particularly, light traveling toward the drain electrode 212, from among visible light generated by the intermediate layer 240), light efficiency may be further improved.

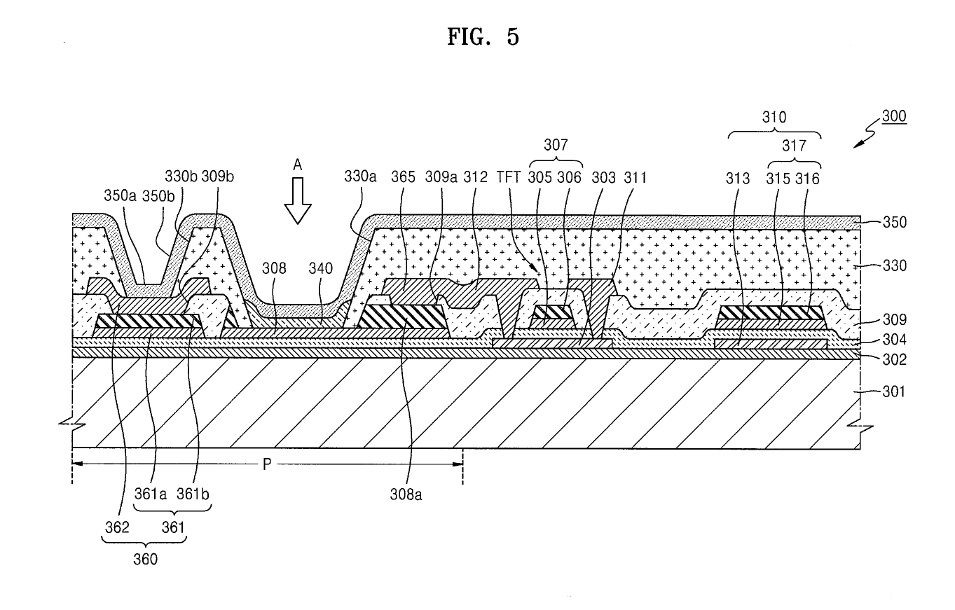

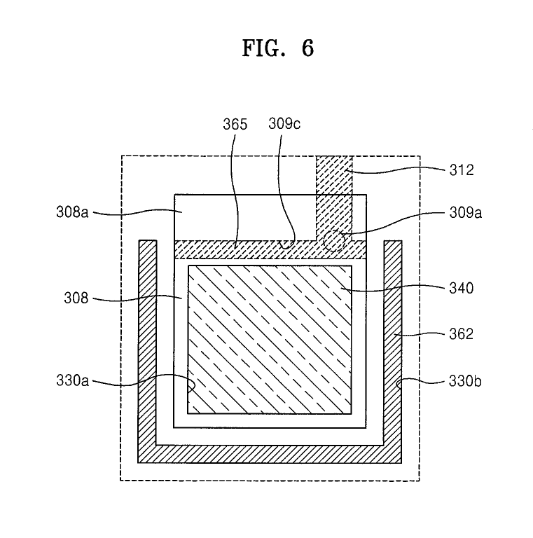

FIG. 5 is a cross-sectional view illustrating an organic light-emitting display apparatus 300 according to another embodiment of the present invention. FIG. 6 is a partial plan view illustrating a portion P of the organic light-emitting display shown in FIG. 5 and seen in an “A” direction (i.e., the direction of the arrow indicated by reference character “A” in FIG. 5). For convenience of explanation, an intermediate layer 340, a first electrode 308, a conductive portion 308a, a second member 362 of a reflective member 360, a drain electrode 312, a reflective layer 365, a contact hole 309a, a second via hole 309c, a first opening 330a, and a second opening 330b are illustrated in FIG. 6.

In order to be easily distinguished from the second member 362 of the reflective member 360 in FIG. 6, the drain electrode 312, the reflective layer 365, and the contact hole 309a are indicated by dashed lines. Also, only a top surface of the second member 362 exposed through the second opening 330b from among surfaces of the second member 362 is illustrated in FIG. 6.

Referring to FIGS. 5 and 6, the organic light-emitting display apparatus 300 includes a substrate 301, a TFT, the first electrode 308, the intermediate layer 340, a second electrode 350, the reflective member 360, the reflective layer 365, and a capacitor 310.

The TFT includes an active layer 303, a gate electrode 307, a source electrode 311, and the drain electrode 312. The capacitor 310 includes a first capacitor electrode 313 and a second capacitor electrode 317. The reflective member 360 includes a first member 361 and the second member 362.

Each element will be explained in detail below.

A buffer layer 302 is formed on the substrate 301, and the active layer 303 and the first capacitor electrode 313 are formed on the buffer layer 302. A gate insulating film 304 is formed on the buffer layer 302 to cover the active layer 303 and the first capacitor electrode 313.

The gate electrode 307, the first electrode 308, the first member 361 of the reflective member 360, and the second capacitor electrode 317 are formed on the gate insulating film 304.

The gate electrode 307 includes a first conductive layer 305 and a second conductive layer 306. The first electrode 308 may include a transparent conductive material and may be formed of the same material as that of the first conductive layer 305.

The conductive portion 308a is formed on a portion of a top surface of the first electrode 308, and is formed of the same material as that of the second conductive layer 306.

The first member 361 of the reflective member 360 is formed to be spaced apart from the first electrode 308. The first member 361 includes a lower layer 361a and an upper layer 361b. The lower layer 361a is formed of the same material as that of the first conductive layer 305 and the upper layer 361b is formed of the same material as that of the second conductive layer 306.

The second capacitor electrode 317 includes a first layer 315 and a second layer 316. The first layer 315 is formed of the same material as that of the first conductive layer 305 and the second layer 316 is formed of the same material as that of the second conductive layer 306.

An interlayer insulating film 309 is formed on the first electrode 308, the gate electrode 307, the first member 361, and the second capacitor electrode 317. The source electrode 311, the drain electrode 312, and the second member 362 of the reflective member 360 are formed on the interlayer insulating film 309. The source electrode 311 and the drain electrode 312 are electrically connected to the active layer 303.

Any one of the source electrode 311 and the drain electrode 312 is electrically connected to the first electrode 308. In the present embodiment, the drain electrode 312 is electrically connected to the first electrode 308 in FIGS. 5 and 6. In detail, the interlayer insulating film 309 includes the contact hole 309a, and a first end of the drain electrode 312 longitudinally extends to contact the conductive portion 308a via the contact hole 309a.

The second member 362 is formed on the first member 361. In detail, the interlayer insulating film 309 includes a first via hole 309b. The second member 362 is formed to correspond to the first via hole 309b.

The reflective layer 365 is formed on the conductive portion 308a. In detail, the interlayer insulating film 309 includes the second via hole 309c, and the reflective layer 365 is formed to correspond to the second via hole 309c. The reflective layer 365 longitudinally extends to correspond to a side surface of the intermediate layer 340, and is spaced apart from the reflective member 360.

The reflective layer 365 is formed to be electrically connected to the drain electrode 312. In detail, the contact hole 309a is formed to communicate with (e.g., to be connected to) the second via hole 309c, and the reflective layer 365 is electrically connected to the drain electrode 312.

A pixel defining layer 330 is formed on the TFT and on the reflective member 360 to expose a portion of the top surface of the first electrode 308, and the intermediate layer 340 is formed to contact the first electrode 308. The intermediate layer 340 includes an organic light-emitting layer (not shown).

In detail, the pixel defining layer 330 includes the first opening 330a and the second opening 330b. The first opening 330a is formed to correspond to the portion of the top surface of the first electrode 308, and the intermediate layer 340 is formed in the first opening 330a and is electrically connected to the first electrode 308.

The second opening 330b of the pixel defining layer 330 is formed to correspond to a portion of a top surface of the second member 362 of the reflective member 360. In the present embodiment, at least a surface of the second opening 330b adjacent to the intermediate layer 340 from among surfaces of the second opening 330b (e.g., surfaces of the pixel defining layer 330 in the second opening 330b) may be inclined at an angle (e.g., an acute angle) with respect to the substrate 301. For example, a width of the second opening 330b may increase upward from the substrate 301, that is, away from the substrate 301.

The second electrode 350 is formed on the intermediate layer 340 to correspond to the second opening 330b and is electrically connected to the reflective member 360. In detail, the second electrode 350 includes a contact portion 350a contacting the second member 362 in the second opening 330b and a side portion 350b located at a side of the second opening 330b.

The reflective member 360 is formed around the intermediate layer 340 (e.g., on three sides of the intermediate layer 340, see FIG. 6). In detail, the reflective member 360 may be formed to correspond to a side surface other than a side surface of the intermediate layer 340 adjacent to the conductive portion 308a from among side surfaces of the intermediate layer 340.

The second opening 330b is formed around the intermediate layer 340 to correspond to the reflective member 360, and the second electrode 350 is formed in the second opening. Accordingly, the contact portion 350a and the side portion 350b of the second electrode 350 may be formed to correspond to the side surface of the intermediate layer 340. In detail, the contact portion 350a and the side portion 350b of the second electrode 350 may be formed to correspond to a side surface other than a side surface of the intermediate layer 340 adjacent to the conductive portion 308a from among side surfaces of the intermediate layer 340.

The reflective member 360 includes the first member 361 and the second member 362 in FIGS. 5 and 6. However, the first member 361 and the second member 362 might not be separately formed, but may instead be integrally formed with each other. That is, the reflective member 360 may be formed of the same material as that of the gate electrode 307, and the reflective member 360 may be formed of the same material as that of the source electrode 311 or the drain electrode 312.

A sealing member (not shown) may be formed on the second electrode 350 to protect the intermediate layer 340 and other layers from external moisture or oxygen. To this end, the sealing member may be formed of any of various materials such as glass, plastic, an organic material, an inorganic material, or a combination of an organic material and an inorganic material.

In the organic light-emitting display apparatus 300 of the present embodiment, the reflective member 360 is formed to correspond to the side surface of the intermediate layer 340. Accordingly, the light efficiency of the organic light-emitting display apparatus 300 is improved, thereby improving image quality.

The side portion 350b and the contact portion 350a of the second electrode 350 formed on the reflective member 360 effectively reduces or prevents light traveling from the side surface of the intermediate layer 340 from among visible light generated by the intermediate layer 340 from being outwardly discharged away from the user, and effectively leads to light reflection in the organic light-emitting display apparatus 300, thereby improving light efficiency through optical resonance.

Also, since the conductive portion 308a and the reflective layer 365 electrically connected to the conductive portion 308a reflect light traveling from the side surface of the intermediate layer 340 from among visible light generated by the intermediate layer 340 to the user, light efficiency may be further improved.

According to the present invention, an organic light-emitting display apparatus may improve image quality.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. An organic light-emitting display apparatus comprising:
a substrate;
a first electrode on the substrate;
an intermediate layer on the first electrode, and comprising an organic light-emitting layer;
a second electrode on the intermediate layer; and
a reflective member on sides of the intermediate layer to reflect visible light generated by the intermediate layer, the reflective member contacting the second electrode.

2. The organic light-emitting display apparatus of claim 1, further comprising a pixel defining layer between the reflective member and the second electrode,
wherein the pixel defining layer comprises:
a first opening corresponding to the intermediate layer; and
a second opening corresponding to the reflective member, and
wherein the reflective member and the second electrode contact each other in the second opening.

3. The organic light-emitting display apparatus of claim 2, wherein the second opening extends corresponding to at least one side surface of the intermediate layer.

4. The organic light-emitting display apparatus of claim 2, wherein a width of the second opening increases away from the substrate.

5. The organic light-emitting display apparatus of claim 2, wherein the second electrode comprises:
a contact portion contacting a top surface of the reflective member in the second opening; and
a side portion at a side of the second opening.

6. The organic light-emitting display apparatus of claim 5, wherein a surface of the side portion of the second electrode adjacent to the intermediate layer is at an angle with the substrate.

7. The organic light-emitting display apparatus of claim 1, wherein the reflective member extends corresponding to at least one side surface of the intermediate layer.

8. The organic light-emitting display apparatus of claim 1, wherein the reflective member is spaced from the first electrode.

9. The organic light-emitting display apparatus of claim 1, further comprising a thin film transistor (TFT) on the substrate, the TFT being electrically connected to the first electrode, and comprising an active layer, a gate electrode, a source electrode, and a drain electrode.

10. The organic light-emitting display apparatus of claim 9, wherein the reflective member is spaced from the source electrode and the drain electrode.

11. The organic light-emitting display apparatus of claim 9, wherein the reflective member comprises a same material as the gate electrode, the source electrode, or the drain electrode.

12. The organic light-emitting display apparatus of claim 9, wherein the reflective member comprises:
a first member comprising a same material as the gate electrode; and
a second member on the first member and comprising a same material as the source electrode and/or the drain electrode.

13. The organic light-emitting display apparatus of claim 9, further comprising a conductive member on the first electrode and electrically connected to the source electrode or the drain electrode.

14. The organic light-emitting display apparatus of claim 13, further comprising a reflective layer on the conductive member.

15. The organic light-emitting display apparatus of claim 14, wherein the reflective layer extends corresponding to a side surface of the intermediate layer.

16. The organic light-emitting display apparatus of claim 14, wherein the reflective layer is spaced from the reflective member.

17. The organic light-emitting display apparatus of claim 14, wherein the reflective layer is spaced from the source electrode and the drain electrode.

18. The organic light-emitting display apparatus of claim 14, wherein the reflective layer is electrically connected to any one of the source electrode and the drain electrode,
wherein the source electrode or the drain electrode electrically connected to the reflective layer is electrically connected to the first electrode.

19. The organic light-emitting display apparatus of claim 9, wherein the gate electrode and the first electrode are at a same layer.

20. The organic light-emitting display apparatus of claim 9, wherein
the gate electrode comprises:
a first conductive layer; and
a second conductive layer on the first conductive layer,
wherein the first electrode comprises a same material as the first conductive layer, and
wherein the reflective member comprises:
a first member comprising:
a lower layer comprising a same material as the first conductive layer of the gate electrode; and
an upper layer on the lower layer and comprising a same material as the second conductive layer of the gate electrode; and
a second member on the first member and comprising a same material as the source electrode and/or the drain electrode.
